(19) United States
(12) Patent Application Publication
(10) Pub. No.: US 2014/0054079 A1
(43) Pub. Date: Feb. 27, 2014

(54) MULTILAYER FLEXIBLE PRINTED CIRCUIT BOARD AND METHOD FOR MANUFACTURING SAME

(71) Applicants: ZHEN DING TECHNOLOGY CO., LTD., Tayuan (TW); FuKui Precision component (Shenzhen) Co., Ltd., Shenzhen (CN)

(72) Inventors: FU-YUN SHEN, Shenzhen (CN); ZHI-TIAN WANG, Shenzhen (CN)

(73) Assignees: ZHEN DING TECHNOLOGY CO., LTD., Tayuan (TW); FUKUI PRECISION COMPONENT (SHENZHEN) CO., LTD., Shenzhen (CN)

(21) Appl. No.: 13/957,785

(22) Filed: Aug. 2, 2013

(30) Foreign Application Priority Data
Aug. 22, 2012 (CN) 2012103001435

(51) Int. Cl. H05K 1/02; H05K 3/46

(52) U.S. Cl. CPC H05K 1/0277; H05K 3/4611
USPC 174/262; 216/20

(57) ABSTRACT

A method for manufacturing a multilayer FPCB includes certain steps. A first printed circuit substrate is provided, the first printed circuit substrate includes a first copper layer and a first protective film, the film defining a first opening. A second printed circuit substrate is provided, this substrate includes a second copper layer and a second protective film. The second protective film defines a second opening. The first printed circuit substrate is laminated together with the second printed circuit substrate by an adhesive sheet. The adhesive sheet defines a third opening in communication with and aligned with the first opening and the second opening. The first copper layer is then etched to form a first outer wiring layer and the third copper layer is also etched to form a second outer wiring layer, thereby obtaining a multilayer FPCB.

### BACKGROUND

1. Technical Field

The present disclosure relates to printed circuit boards, particularly to a multilayer flexible printed circuit board and a method for manufacturing the same.

2. Description of Related Art

Flexible printed circuit boards (FPCB) are widely used in consumer electronic products such as laptop, liquid crystal display, digital camera and mobile phone due to their special characteristics such as flexibility, low weight and thinness.

The FPCBs are expected to be multilayer FPCBs to provide more wiring areas. The flexibility of the multilayer FPCB decreases as the number of wiring layers of the multilayer FPCB increases. When the number of the wiring layers of the multilayer FPCB is more than three, the multilayer FPCB will have a rigidity close to that of a rigid printed circuit board, which is bad for the FPCB.

What is needed, therefore, is to that can overcome the described limitations.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is a schematic, cross-sectional view of a first double-sided copper clad laminate according to a first embodiment.

FIG. 2 is a schematic, cross-sectional view of a first inner wiring layer formed by selectively etching a second copper layer of the double-sided copper clad laminate of FIG. 1.

FIG. 3 is a schematic, cross-sectional view of a first printed circuit substrate obtained by laminating a first protective film on the first inner wiring layer of the double-sided copper clad laminate of FIG. 2.

FIG. 4 is a schematic, cross-sectional view of a second double-sided copper clad laminate according to the first embodiment.

FIG. 5 is a schematic, cross-sectional view of a second inner wiring layer formed by selectively etching a fourth copper layer of the second double-sided copper clad laminate of FIG. 4.

FIG. 6 is a schematic, cross-sectional view of a second printed circuit substrate obtained by laminating a second protective film on the second inner wiring layer of the second double-sided copper clad laminate of FIG. 5.

FIG. 7 is a schematic, cross-sectional view of a third printed circuit substrate obtained by laminating the first printed circuit substrate of FIG. 3, an adhesive sheet, and the second printed circuit substrate of FIG. 6, in that order.

FIG. 8 shows a plurality of conductive vias defined in the third printed circuit substrate of FIG. 7.

FIG. 9 shows a first outer wiring layer formed by selectively etching a first copper layer and a first top copper layer, and a second outer wiring layer formed by selectively etching a third copper layer and a second top copper layer of the third printed circuit substrate of FIG. 8.

FIG. 10 is a schematic, cross-sectional view of a multilayer FPCB obtained by laminating a third protective film on the first outer wiring layer and laminating a fourth protective film on the second outer wiring layer in FIG. 9.

FIG. 11 shows a second inner wiring layer formed by selectively etching a fourth copper layer of the second double-sided copper clad laminate of FIG. 4.

FIG. 12 is a schematic, cross-sectional view of a second printed circuit substrate obtained by laminating a second protective film on the second inner wiring layer of the second double-sided copper clad laminate of FIG. 11.

FIG. 13 is a schematic, cross-sectional view of a third printed circuit substrate obtained by laminating the first printed circuit substrate of FIG. 3, an adhesive sheet, and the second printed circuit substrate of FIG. 12, in that order.

FIG. 14 shows a plurality of conductive vias defined in the third printed circuit substrate of FIG. 13.

FIG. 15 shows a first outer wiring layer formed by selectively etching a first copper layer and a first top copper layer, and a second outer wiring layer formed by selectively etching a third copper layer and a second top copper layer in FIG. 14.

FIG. 16 is a schematic, cross-sectional view of a multilayer FPCB obtained by laminating a third protective film on the first outer wiring layer and laminating a fourth protective film on the second outer wiring layer in FIG. 15.

### DETAILED DESCRIPTION

A multilayer FPCB and a method of manufacturing the multilayer FPCB will be described with reference to the drawings.

A method for manufacturing a multilayer PCB according to a first embodiment includes the following steps.

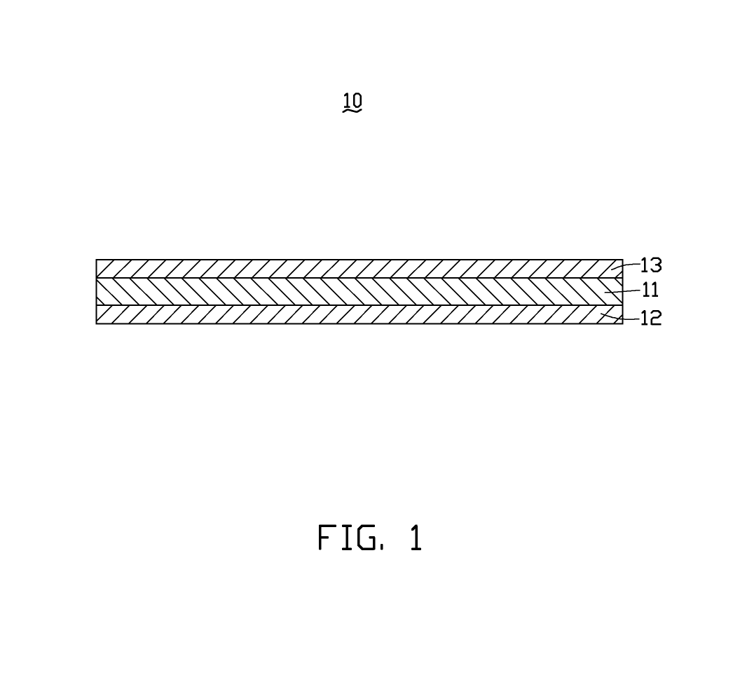

FIG. 1 shows that in step (1) a first double-sided copper clad laminate 10 is provided.

The first double-sided copper clad laminate 10 includes a first insulating layer 11, a first copper layer 12 and a second copper layer 13. The first copper layer 12 and the second copper layer 13 are located at opposite sides of the first insulating layer 11. The first insulating layer 11 is comprised of a flexible material such as polyimide (PI), polyethylene terephtalate (PET), or Polyethylene naphthalate (PEN).

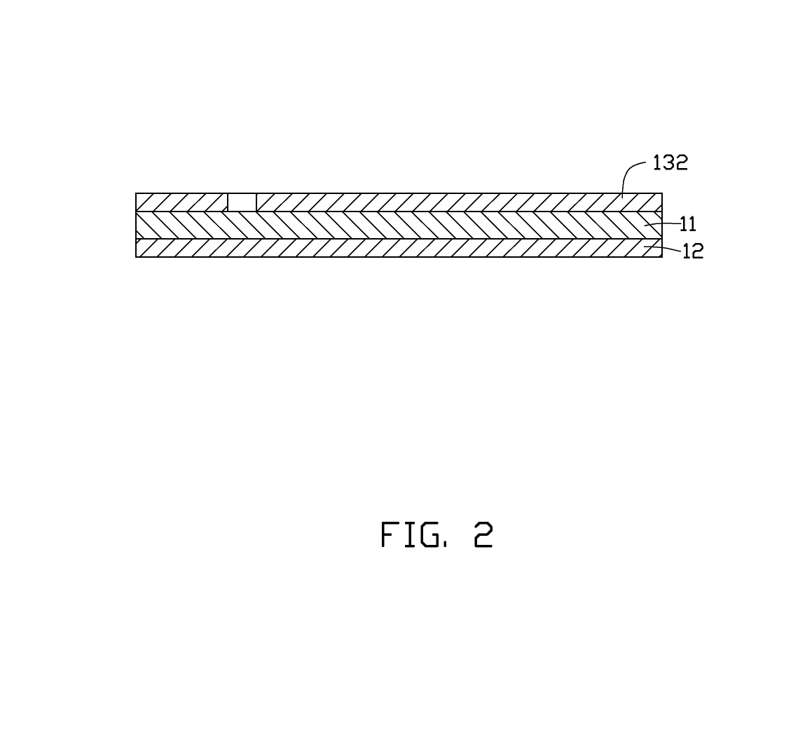

FIG. 2 shows that in step (2) the second copper layer 13 is selectively etched, thereby forming a first inner wiring layer 132. The first inner wiring layer 132 can be formed by using a photolithography process and an etching process.

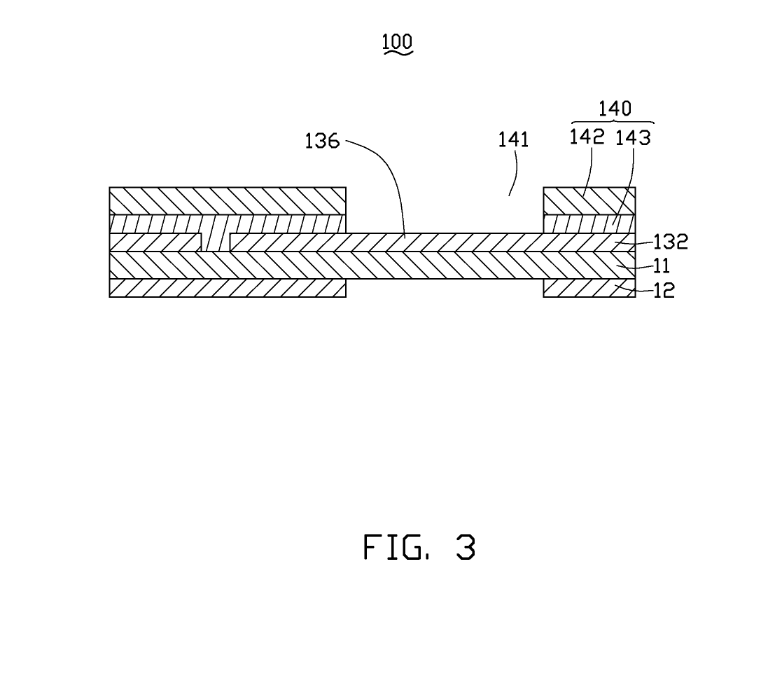

FIG. 3 shows that in step (3) a first protective film 140 is laminated on the first inner wiring layer 132, thereby obtaining a first printed circuit substrate 100.

A first opening 141 is defined in the first protective film 140. In this embodiment, the first protective film 140 includes a first polyimide layer 142 and a first adhesive layer 143. The first adhesive layer 143 is adhered with the first inner wiring layer 132. The first inner wiring layer includes a plurality of first parallel wirings 136 in a portion thereof aligned with the first opening 141.

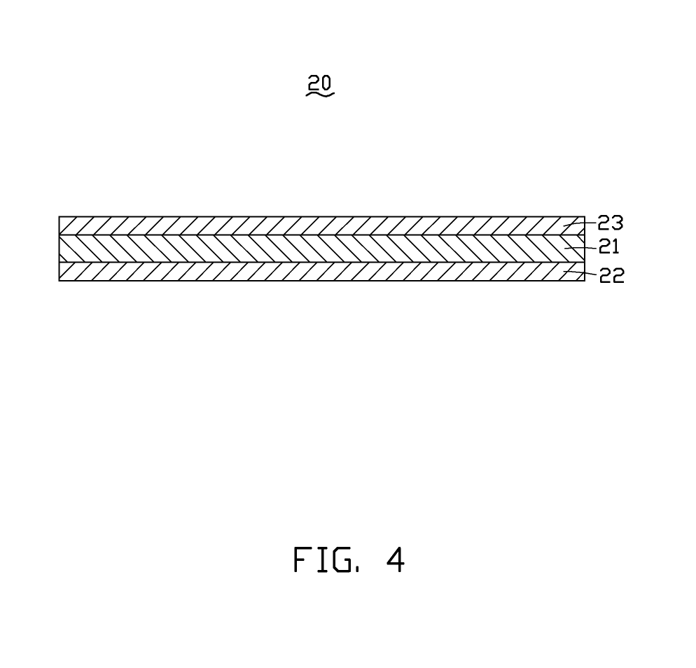

FIG. 4 shows that in step (4) a second double-sided copper clad laminate 20 is provided.

The second double-sided copper clad laminate 20 includes a second insulating layer 21, a third copper layer 22 and a fourth copper layer 23. The third copper layer 22 and the fourth copper layer 23 are formed on opposite sides of the second insulating layer 21. The second insulating layer 21 is comprised of a flexible material such as polyimide (PI), polyethylene terephtalate (PET), or polyethylene naphthalate (PEN).

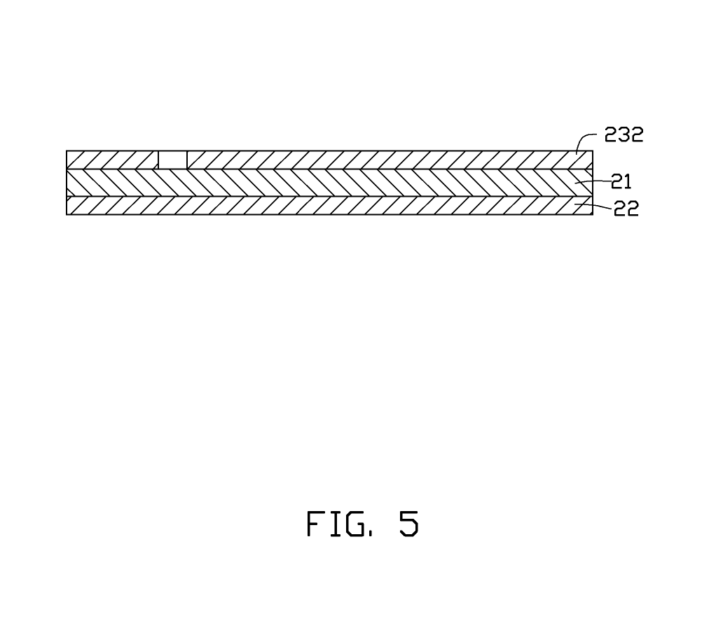

FIG. 5 shows that in step (5) the fourth copper layer 23 is selectively etched, thereby forming a second inner wiring layer 232. The second inner wiring layer 232 can be formed by using a photolithography process and an etching process.

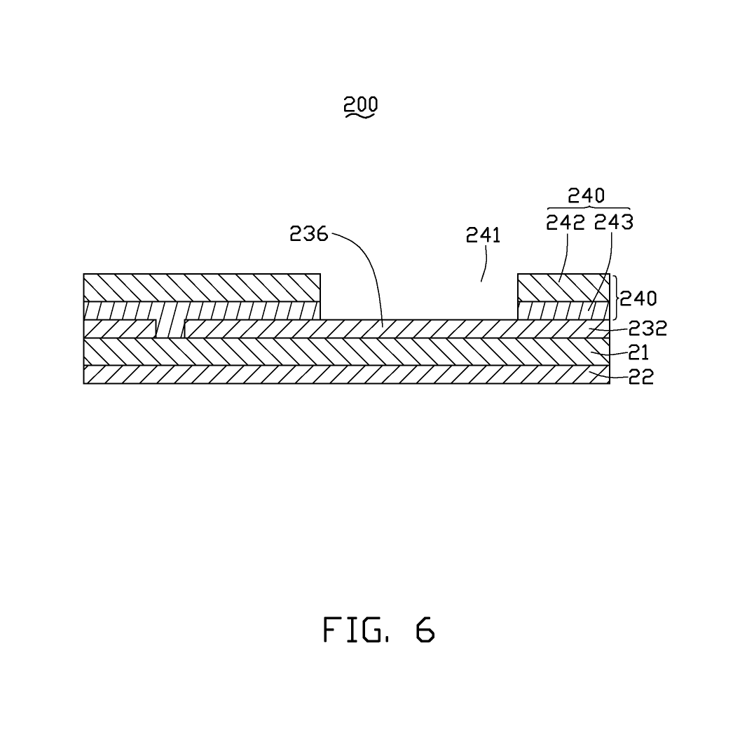

FIG. 6 shows that in step (6) a second protective film 240 is laminated on the second inner wiring layer 232, thereby obtaining a second printed circuit substrate 200.

A second opening 241 is defined in the second protective film 240. A shape of the second opening 241 is same as that of the first opening 141. The second opening 241 has an area equal to that of the first opening 141. In this embodiment, the second protective film 240 includes a second polyimide layer 242 and a second adhesive layer 243 with one side attached to the polyimide layer 242. An opposite side of second adhesive layer 243 is attached to the second inner wiring layer 232. The second inner wiring layer 232 includes a plurality of second parallel wirings 236 in a portion thereof which is aligned with the second opening 241.

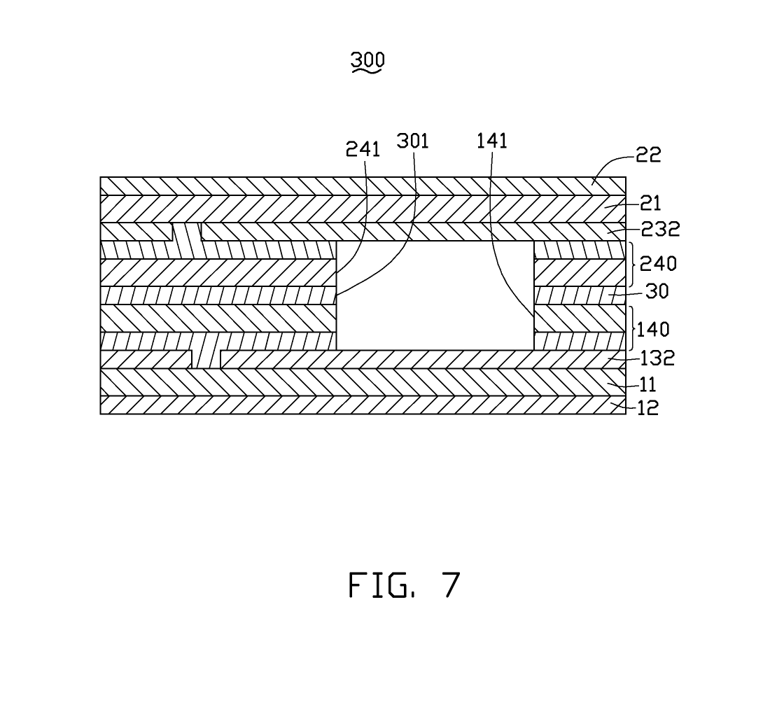

FIG. 7 shows that in step (7) an adhesive sheet 30 is provided. Then the first printed circuit substrate 100 and the second printed circuit substrate 200 are laminated on opposite sides of the adhesive sheet 30, thereby obtaining a third printed circuit substrate 300.

A third opening 301 is defined in the adhesive sheet 30. A shape of the third opening 301 is same as that of the first opening 141. An area of the third opening 301 is equal to or slightly greater than that of the first opening 141.

The first copper layer 12 and the third copper layer 22 are located at opposite sides of the third printed circuit substrate 300. The third opening 301 is aligned with and in communication with the first opening 141 and the second opening 241. Thus, the third opening 301, the first opening 141 and the second opening 241 cooperatively form a large space.

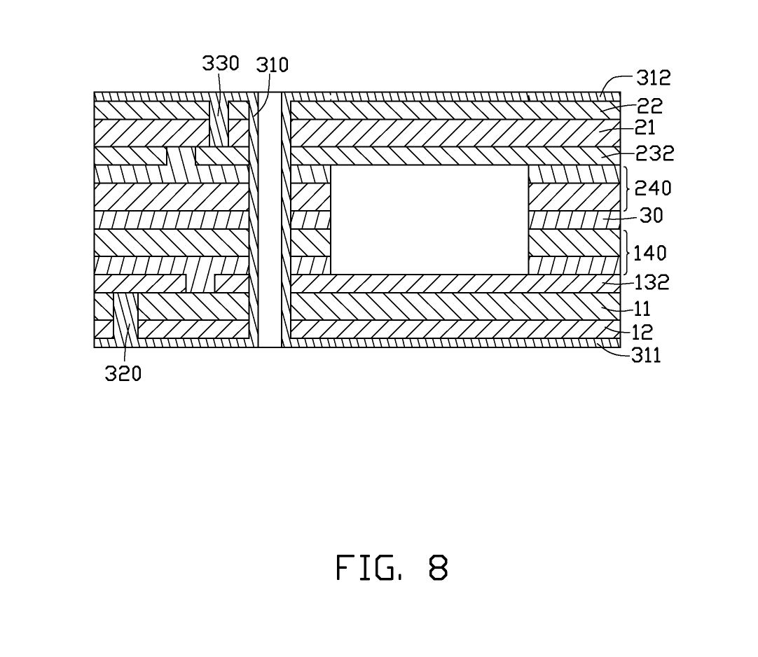

FIG. 8 shows that in step (8) a first conductive via 310, a second conductive via 320 and a third conductive via 330 are formed in the third printed circuit substrate 300.

The first conductive via 310 is a conductive through via electrically connected to the first copper layer 12, the first inner wiring layer 132, the second inner wiring layer 232 and the third copper layer 22. The second conductive via 320 and the third conductive via 330 are conductive blind vias. The second conductive via 320 is formed in the first copper layer 12 and the first insulating layer 11, and terminates at the first inner wiring layer 132, thereby electrically interconnecting the first copper layer 12 and the first inner wiring layer 132. The third conductive via 330 is formed in the third copper layer 22 and the second insulating layer 21, and terminates at the second inner wiring layer 232, thereby electrically interconnecting the third copper layer 22 and the second inner wiring layer 232. In this embodiment, the first, second and third conductive vias 310, 320, 330 are formed by an electrochemical deposition process. A first outer copper layer 311 is formed on the first copper layer 12, and a second outer copper layer 312 is formed on the third copper layer 22 by the electrochemical deposition process at the same time.

In an alternative embodiment, the second conductive via 320 can be formed after the process of step (1). The third conductive via 330 can be formed after the process of step (3). Accordingly, the second conductive via 320 electrically connects the first copper layer 12 and the second copper layer 13. The third conductive via 330 electrically connects the third copper layer 22 and the fourth copper layer 23. The first outer copper layer 311 on the first copper layer 12 and the second outer copper layer 312 on the second copper layer 22 can be omitted.

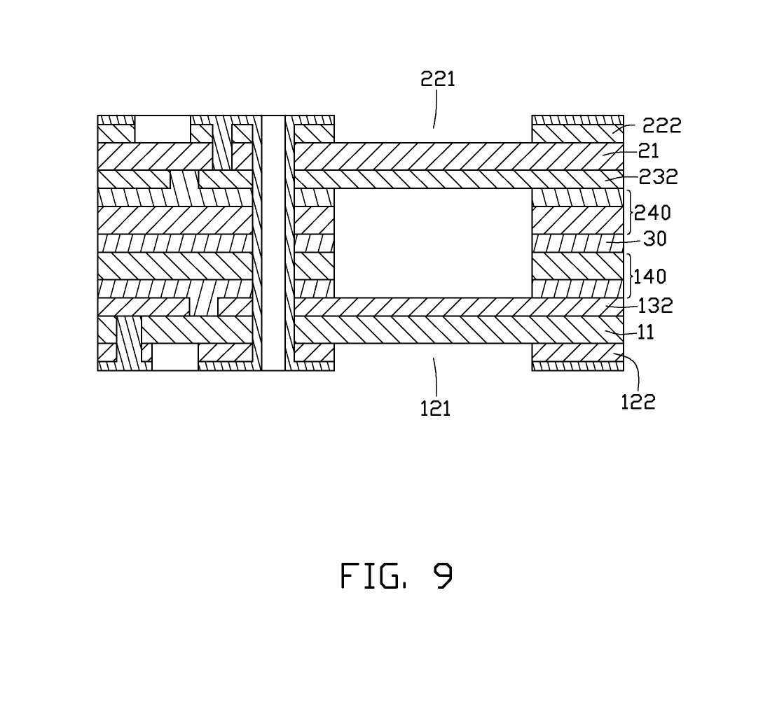

FIG. 9 shows that in step (9) a first outer wiring layer 122 is formed by selectively etching the first copper layer 12 and the first outer copper layer 311. A second outer wiring layer 222 is formed by selectively etching the third copper layer 22 and the second outer copper layer 312.

The first outer wiring layer 122 and the second outer wiring layer 222 can be formed by using a photolithography process and an etching process. A fourth opening 121 is defined in the first outer wiring layer 122. A shape of the fourth opening 121 is same as that of the first opening 141. The fourth opening 121 has an area equal to that of the first opening 141, and is aligned with the first opening 141. A fifth opening 221 is defined in the second outer wiring layer 222. A shape of the fifth opening 221 is same as that of the first opening 141. The fifth opening 221 has an area equal to that of the first opening 141, and is aligned with the first opening 141.

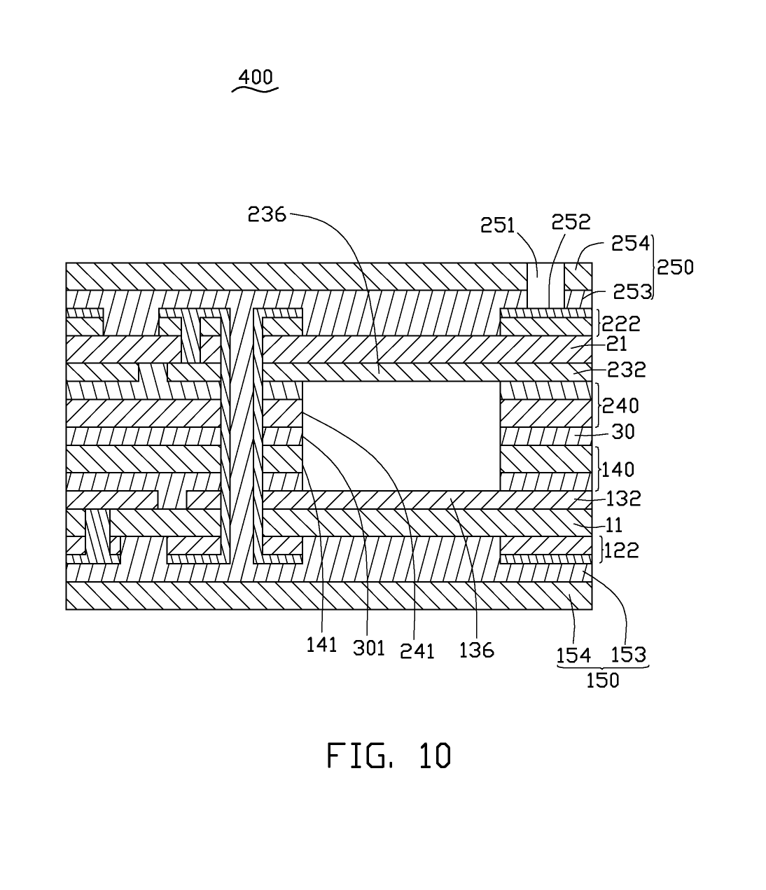

FIG. 10 shows that in step (10) a third protective film 150 is laminated on the first outer wiring layer 122, and a fourth protective film 250 is laminated on the second outer wiring layer 222, thereby obtaining a multilayer FPCB 400.

A sixth opening 251 is defined in the fourth protective film 250. A portion of the second outer wiring layer 222 is exposed through the sixth opening 251. The portion of the second outer wiring layer 222 exposed through the sixth opening 251 serves as a contact pad 252 for mounting an electronic component thereon. The sixth opening 251 can also be defined in the third protective film 150 to expose a portion of the first outer wiring layer 122. In this embodiment, the third protective film 150 includes a third polyimide layer 154 and a third adhesive layer 153 with a side attached to the third polyimide layer 154. An opposite side of the third adhesive layer 153 is attached to the first outer wiring layer 122. The fourth protective film 250 includes a fourth polyimide layer 254 and a fourth adhesive layer 253 with a side attached to the fourth polyimide layer 254. An opposite side of the fourth adhesive layer 253 is attached to the second outer wiring layer 222.

The multilayer FPCB 400 includes the third protective film 150, the first outer wiring layer 122, the first insulating layer 11, the first inner wiring layer 132, the first protective film 140, the adhesive sheet 30, the second protective film 240, the second inner wiring layer 232, the second protective film 21, the second outer wiring layer 222 and the fourth protective film 250. The third opening 301 is defined in the adhesive sheet 30. The first opening 141 is defined in the first protective film 140. The second opening 241 is defined in the second protective film 240. The third opening 301 is aligned with and in communication with the first opening 141 and the second opening 241.

Each multilayer FPCB has a connecting portion and a flexible portion. The connecting region is electrically connected to other electronic devices or elements such as a rigid motherboard. The connecting portion of multilayer FPCB is always rigid. The flexible portion of the multilayer FPCB is required to be as flexible as possible. In this embodiment, the flexible portion of the multilayer FPCB 400 is located where it is aligned with the first opening 141. The connecting portion of the multilayer FPCB 400 is adjacent to the flexible portion of the multilayer FPCB 400. The flexibility of a copper layer is less than the flexibility of an insulating film in an FPCB, so the flexibility of multilayer FPCBs becomes lower with an increasing number of wiring layers. In this embodiment, the connecting portion includes four wiring layers, i.e. the first outer wiring layer 122, the second outer wiring layer 222, the first inner wiring layer 132 and the second inner wiring layer 232. The flexible portion of the multilayer FPCB 400 includes only two wiring layers, i.e. the first inner wiring layer 132 and the second inner wiring layer 232. Therefore, the flexible portion of the multilayer FPCB 400 is more flexible than the connection portion. In addition, there is no first outer wiring layer 122 and no second outer wiring layer 222 in the flexible portion of the multilayer FPCB 400. When the flexible portion of the multilayer FPCB 400 is bent with the third protective film 150 or the fourth protective film 250 being inside the bend, the first inner wiring layer 132 and the second inner wiring layer 232 have a bending radius larger than that of the inside protective film. Thus, the flexible portion of the multilayer FPCB 400 is bent more easily than an FPCB which has the first and second outer wiring layers 122 and 222 arranged within the flexible portion.

A method for manufacturing a multilayer PCB according to the second embodiment includes the following steps.

Steps (1) to (4) of this embodiment are same as steps 1 to 4 of the first embodiment.

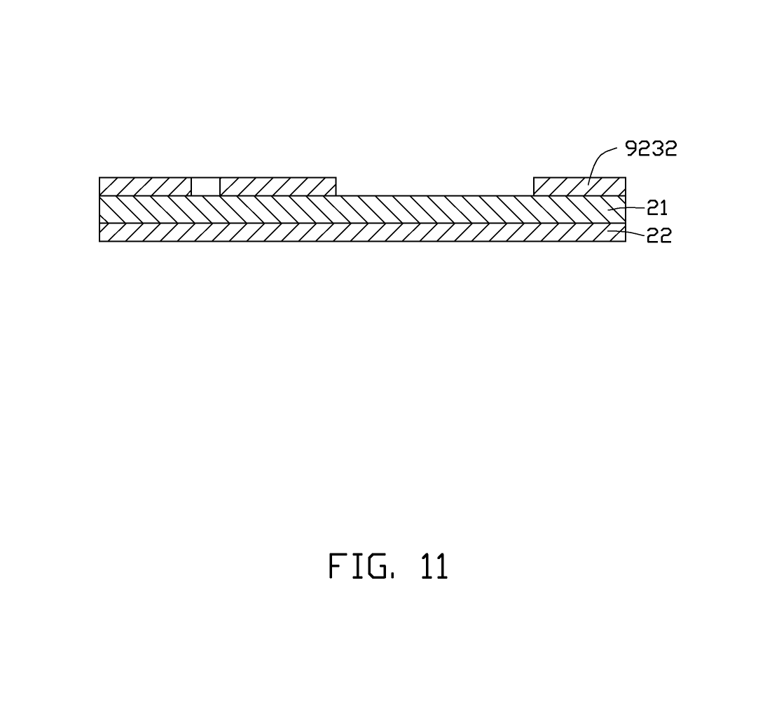

FIG. 11 shows that in step (5) the fourth copper layer 23 is selectively etched, thereby forming a second inner wiring layer 9232.

The second inner wiring layer 9232 can be formed by using a photolithography process and an etching process. A fifth opening 9221 is defined in the second inner wiring layer 9232. A shape of the fifth opening 9221 is same as that of the first opening 141. The fifth opening 9221 has an area equal to that of the first opening 141.

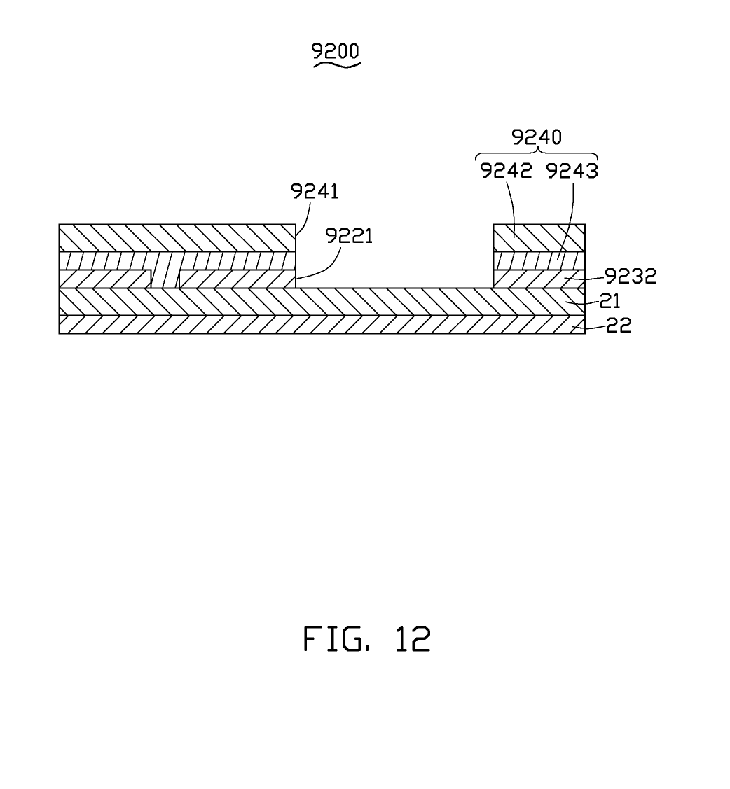

FIG. 12 shows that in step (6) a second protective film 9240 is laminated on the second inner wiring layer 9232, thereby obtaining a second printed circuit substrate 9200.

A second opening 9241 is defined in the second protective film 9240. A shape of the second opening 9241 is same as that of the first opening 141. The second opening 9241 has an area equal to that of the first opening 141. In this embodiment, the second protective film 9240 includes a second polyimide layer 9242 and a second adhesive layer 9243 with a side attached to the second polyimide layer 9242. An opposite side of the second adhesive layer 9243 is attached to the second inner wiring layer 9232.

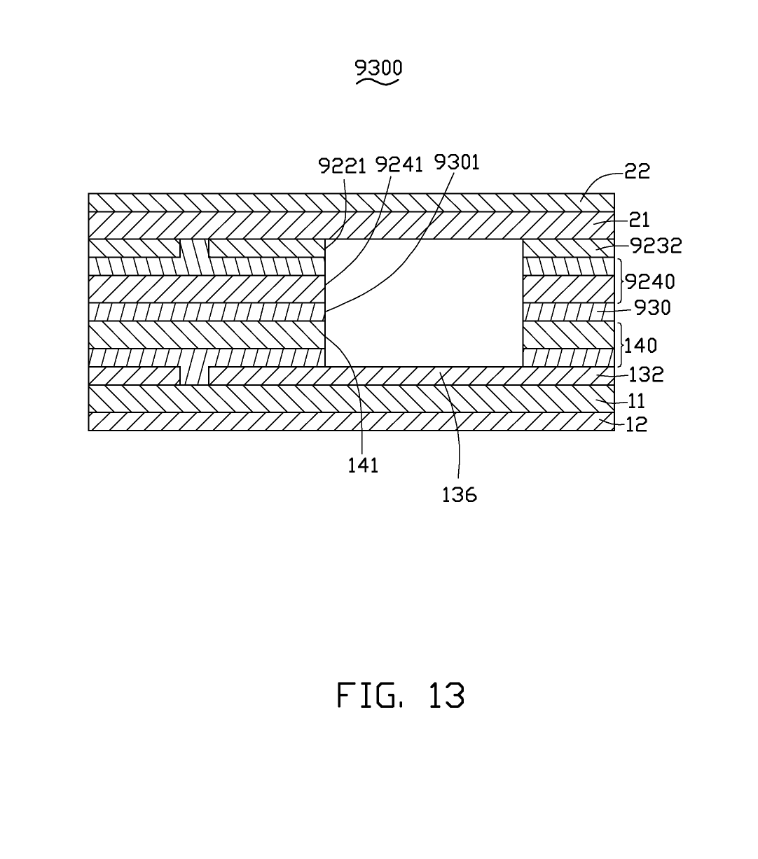

FIG. 13 shows that in step (7) an adhesive sheet 930 is provided. Then the first printed circuit substrate 100 and the second printed circuit substrate 9200 are laminated on opposite sides of the adhesive sheet 930, thereby obtaining a third printed circuit substrate 9300.

A third opening 9301 is defined in the adhesive sheet 930. A shape of the third opening 9301 is same as that of the first opening 141. An area of the third opening 9301 is equal to or slightly greater than that of the first opening 141.

The first copper layer 12 and the third copper layer 22 are located at two opposite sides of the third printed circuit substrate 9300. The third opening 9301 is aligned with and in communication with the first opening 141, the second opening 9241 and the fifth opening 9221. Thus, the first opening 141, the third opening 9301, the second opening 9241 and the fifth opening 9221 cooperatively form a large space.

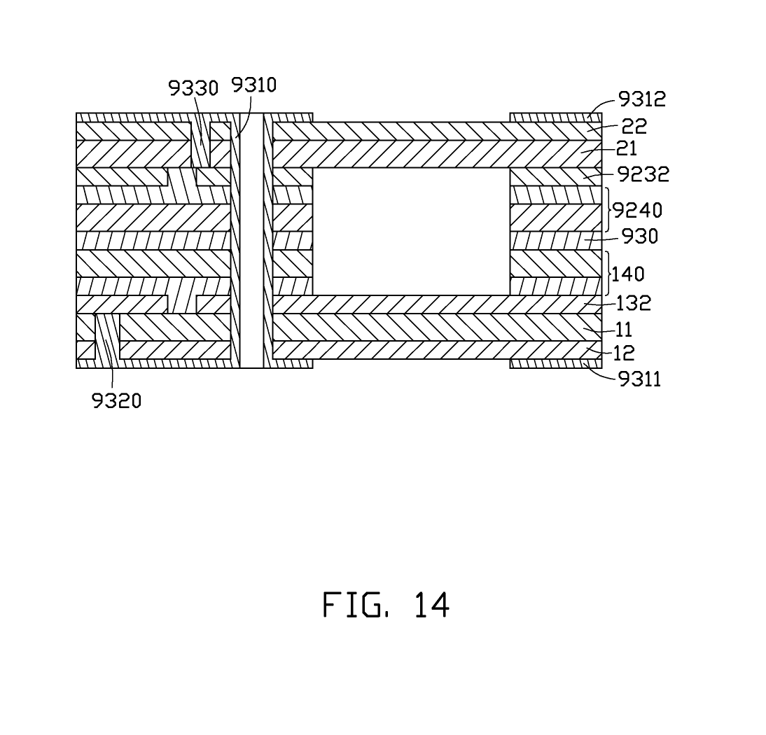

FIG. 14 shows that in step (8) a first conductive via 9310, a second conductive via 9320 and a third conductive via 9330 are formed in the third printed circuit substrate 9300.

The first conductive via 9310 is a conductive through via electrically connected to the first copper layer 12, the first inner wiring layer 132, the second inner wiring layer 9232 and the third copper layer 22. The second conductive via 9320 and the third conductive via 9330 are conductive blind vias. The second conductive via 9320 is formed in the first copper layer 12 and the first insulating layer 11, and terminates at the first inner wiring layer 132, thereby electrically interconnecting the first copper layer 12 and the first inner wiring layer 132. The third conductive via 9330 is formed in the third copper layer 22 and the second insulating layer 21, and terminates at the second inner wiring layer 9232, thereby electrically interconnecting the third copper layer 22 and the second inner wiring layer 9232. In this embodiment, the first, second and third conductive vias 9310, 9320, and 9330 are formed by an electrochemical deposition process. A first outer copper layer 9311 is formed on the first copper layer 12, and a second outer copper layer 9312 is formed on the third copper layer 22 by the electrochemical deposition process at the same time.

In an alternative embodiment, the second conductive via 9320 can be formed after the process of step (1). The third conductive via 9330 can be formed after the process of step (3). Accordingly, the second conductive via 9320 electrically connects the first copper layer 12 and the second copper layer 13. The third conductive via 9330 electrically connects the third copper layer 22 and the fourth copper layer 23. The first outer copper layer 9311 on the first copper layer 12 and the second outer copper layer 9312 on the second copper layer 22 can be omitted.

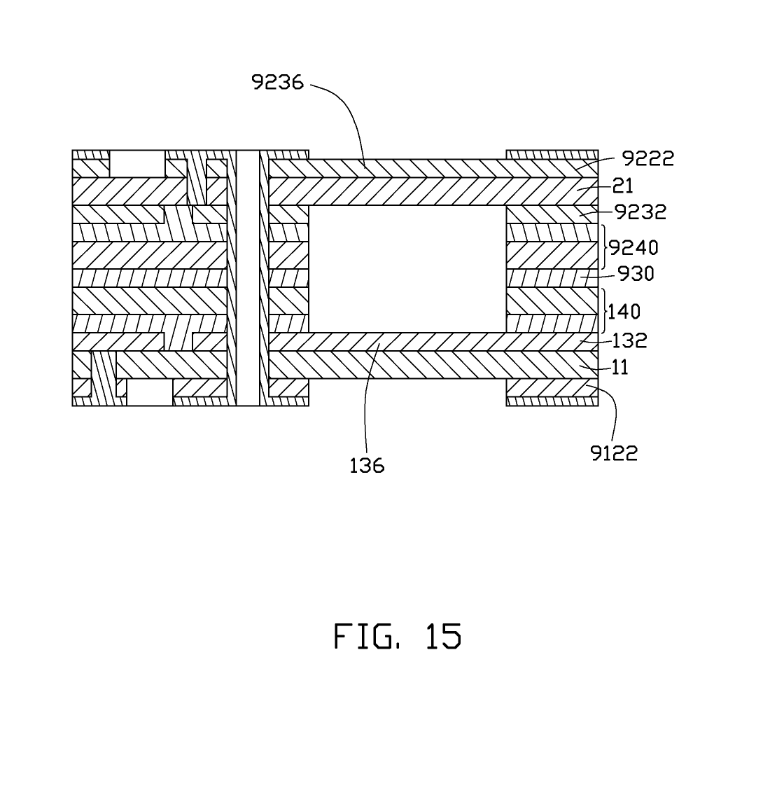

FIG. 15 shows that in step (9) a first outer wiring layer 9122 is formed by selectively etching the first copper layer 12 and the first outer copper layer 9311. A second outer wiring layer 9222 is formed by selectively etching the third copper layer 22 and the second outer copper layer 9312.

The first outer wiring layer 9122 and the second outer wiring layer 9222 can be formed by using a photolithography process and an etching process. A fourth opening 9121 is defined in the first outer wiring layer 9122. A shape of the fourth opening 9121 is same as that of the first opening 141. The fourth opening 9121 has an area equal to that of the first opening 141, and is aligned with the first opening 141. The second outer wiring layer 9222 includes a plurality of second parallel wirings 9236 in a portion thereof which is aligned with the first opening 141.

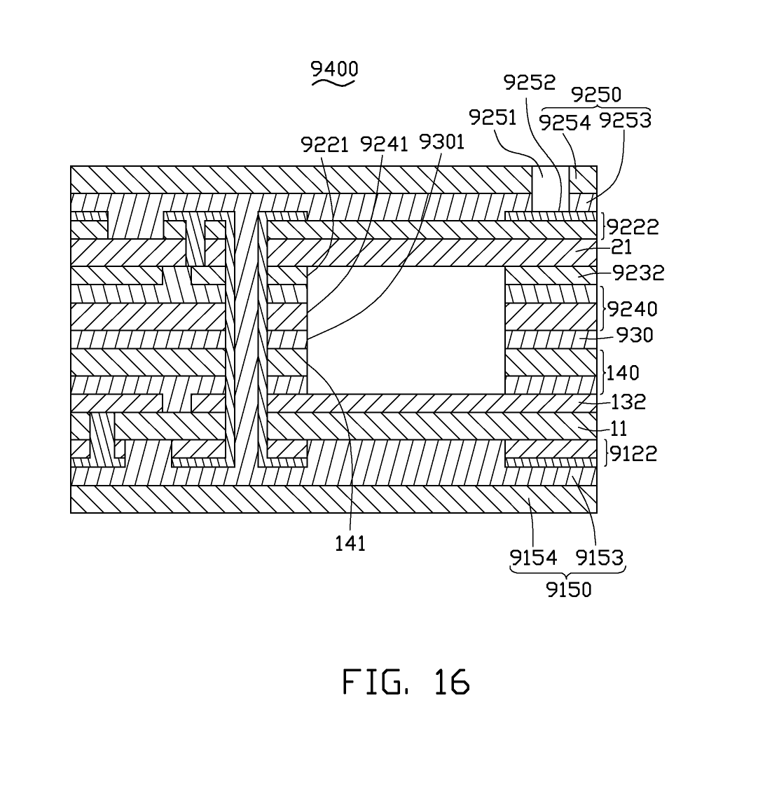

FIG. 16 shows that in step (10) a third protective film 9150 is laminated on the first outer wiring layer 9122 and that a fourth protective film 9250 is laminated on the second outer wiring layer 9222, thereby obtaining a multilayer FPCB 9400.

A sixth opening 9251 is defined in the fourth protective film 9250. A portion of the second outer wiring layer 9222 exposed through the sixth opening 9251 serves as a contact pad 9252 for mounting an electronic component thereon. The sixth opening 9251 can also be defined in the third protective film 9150 to expose a portion of the first outer wiring layer 9122. In this embodiment, the third protective film 9150 includes a third polyimide layer 9154 and a third adhesive layer 9153 with a side attached to the third polyimide layer 9154. An opposite side of the third adhesive layer 9153 is attached to the first outer wiring layer 9122. The fourth protective film 9250 includes a fourth polyimide layer 9254 and a fourth adhesive layer 9253 with a side attached to the fourth polyimide layer 9254. An opposite side of the fourth adhesive layer 9253 is attached to the second outer wiring layer 9222.

The multilayer FPCB 9400 includes the third protective film 9150, the first outer wiring layer 9122, the first insulating layer 11, the first inner wiring layer 132, the first protective film 140, the adhesive sheet 930, the second protective film 9240, the second inner wiring layer 9232, the second protective film 21, the second outer wiring layer 9222 and the fourth protective film 9250. The first opening 141 is defined in the first protective film 140. The second opening 9241 is defined in the second protective film 9240. The third opening 9301 is defined in the adhesive sheet 930. The fourth opening 9221 is defined in the second outer wiring layer 9232. The fifth opening 9121 is defined in the first outer wiring layer 9122. The third opening 9301 is in communication with the first opening 141, the second opening 9241 and the fifth opening 9221.

In this embodiment, the connecting portion includes four wiring layers, i.e. the first outer wiring layer 9122, the second outer wiring layer 9222, the first inner wiring layer 132 and the second inner wiring layer 9232. The flexible portion of the multilayer FPCB 9400 includes only two wiring layers, i.e. the first inner wiring layer 132 and the second outer wiring layer 9222. Therefore, the flexible portion of the multilayer FPCB 9400 is more flexible than the connection portion thereof. In addition, there is no first outer wiring layer 9122 and no second inner wiring layer 9232 in the flexible portion of the multilayer FPCB 9400. When the flexible portion of the multilayer FPCB 9400 is bent with the third protective film 9150 being inside the bend, the first inner wiring layer 132 and the second outer wiring layer 9222 have a bending radius larger than that of the inside third protective film 9150. Thus, the flexible portion of the multilayer FPCB 9400 is bent more easily than an FPCB with the first outer wiring layers 9122 arranged in the flexible portion.

While certain embodiments have been described and exemplified above, various other embodiments will be apparent to those skilled in the art from the foregoing disclosure. The present disclosure is not to be limited to the particular embodiments described and exemplified but is capable of considerable variation and modification without departure from the scope of the appended claims.

What is claimed is:

1. A method for manufacturing a multilayer flexible printed circuit board, comprising:
providing a first printed circuit substrate comprising a first copper layer, a first insulating layer, a first inner wiring layer and a first protective film laminated in that order, the first protective film defining a first opening;
providing a second printed circuit substrate comprising a third copper layer, a second insulating layer, a second inner wiring layer and a second protective film laminated in that order, the second protective film defining a second opening;
providing an adhesive sheet, the adhesive sheet defining a third opening;
laminating the first printed circuit substrate, the adhesive sheet and the second printed circuit substrate in that order, the first protective film and the second protective film adjacent to the adhesive sheet, the third opening being aligned with and in communication with the first opening and the second opening;
etching the first copper layer to form a first outer wiring layer, etching the third copper layer to form a second outer wiring layer, thereby obtaining a multilayer flexible printed circuit board.

2. The method of claim 1, further forming a first, a second and a third conductive via before the step of etching the first copper layer to form a first outer wiring layer and etching the third copper layer to form a second outer wiring layer, the first conductive via electrically connecting the first copper layer, the first inner wiring layer, the second inner wiring layer and the third copper layer, the second conductive via electrically connecting the first copper layer and the first inner wiring layer, the third conductive via electrically connecting the second inner wiring layer and the third copper layer.

3. The method of claim 1, further comprising laminating a third protective film on the first outer wiring layer and laminating a fourth protective film on the second outer wiring layer after etching the first copper layer to form a first outer wiring layer and etching the third copper layer to form a second outer wiring layer.

4. The method of claim 3, wherein the fourth protective film defines a sixth opening therein, a portion of the second outer wiring layer exposed through the sixth opening, the portion of the second outer wiring layer exposed through the sixth opening serving as a contact pad for mounting an electronic component thereon.

5. The method of claim 1, wherein a shape of the second opening is same as that of the first opening, and the second opening has an area equal to that of the first opening.

6. The method of claim 1, wherein the first outer wiring layer defines a fourth opening aligned with the first opening, and the second outer wiring layer defines a fifth opening aligned with the first opening, a shape of the fourth opening being same as that of the first opening, the fourth opening having an area equal to that of the first opening, a shape of the fifth opening being same as that of the first opening, the fifth opening having an area equal to that of the first opening.

7. The method of claim 1, wherein a method for forming the first printed circuit substrate comprising:
providing a first double-sided copper clad laminate comprising the first copper layer, the first insulating layer, a second copper layer, the first copper layer and the second copper layer located at opposite sides of the first insulating layer;
etching the second copper layer to form the first inner wiring layer;
laminating the first protective film on the first inner wiring layer, the first protective film defining the first opening, thereby obtaining a first printed circuit substrate.

8. The method of claim 1, wherein a method for forming the second printed circuit substrate comprising:
providing a second double-sided copper clad laminate comprising the third copper layer, the second insulating layer, a fourth copper layer, the third copper layer and the fourth copper layer located at opposite sides of the second insulating layer;
etching the fourth copper layer to form a second inner wiring layer;
laminating a second protective film on the second inner wiring layer, the second protective film defining a second opening aligned with the first opening, thereby obtaining a second printed circuit substrate.

9. The method of claim 1, wherein a shape of the third opening is same as that of the first opening, an area of the third opening being equal to or greater than that of the first opening.

10. A method for manufacturing a multilayer flexible printed circuit board, comprising:
providing a first printed circuit substrate comprising a first copper layer, a first insulating layer, a first inner wiring layer and a first protective film laminated in that order, the first protective film defining a first opening;
providing a second printed circuit substrate comprising a third copper layer, a second insulating layer, a second inner wiring layer and a second protective film laminated in that order, the second protective film defining a second opening, the second inner wiring layer defining a fifth opening;
providing an adhesive sheet, the adhesive sheet defining a third opening;
laminating the first printed circuit substrate, the adhesive sheet and the second printed circuit substrate in that order, the first protective film and the second protective film adjacent to the adhesive sheet, the third opening being aligned with and in communication with the first opening, the second opening and the fifth opening;
etching the first copper layer to form a first outer wiring layer, etching the third copper layer to form a second outer wiring layer, thereby obtaining a multilayer flexible printed circuit board.

11. The method of claim 10, further forming a first, a second and a third conductive via before the step of etching the first copper layer to form a first outer wiring layer and etching the third copper layer to form a second outer wiring layer, the first conductive via electrically connecting the first copper layer, the first inner wiring layer, the second inner wiring layer and the third copper layer, the second conductive via electrically connecting the first copper layer and the first inner wiring layer, the third conductive via electrically connecting the second inner wiring layer and the third copper layer.

12. The method of claim 10, further comprising laminating a third protective film on the first outer wiring layer and laminating a fourth protective film on the second outer wiring layer after etching the first copper layer to form a first outer wiring layer and etching the third copper layer to form a second outer wiring layer.

13. The method of claim 12, wherein the fourth protective film defines a sixth opening therein, a portion of the second outer wiring layer exposed through the sixth opening, the portion of the second outer wiring layer exposed through the sixth opening serving as a contact pad for mouting an electronic component thereon.

14. The method of claim 10, wherein a shape of the second opening is same as that of the first opening, and the second opening having an area equal to that of the first opening, a shape of the fifth opening being same as that of the first opening, the fifth opening having an area equal to that of the first opening.

15. The method of claim 10, therein the first outer wiring layer defines a fourth opening aligned with the first opening, a shape of the fourth opening being same as that of the first opening, the fourth opening having an area equal to that of the first opening.

16. The method of claim 10, wherein a method for forming the first printed circuit substrate comprising:
providing a first double-sided copper clad laminate comprising the first copper layer, the first insulating layer, a second copper layer, the first copper layer and the second copper layer located at opposite sides of the first insulating layer;
etching the second copper layer to form a first inner wiring layer;
laminating the first protective film on the first inner wiring layer, the first protective film defining the first opening, thereby obtaining a first printed circuit substrate.

17. The method of claim 10, wherein a method for forming the second printed circuit substrate comprising:
providing a second double-sided copper clad laminate comprising the third copper layer, the second insulating layer, a fourth copper layer, the third copper layer and the fourth copper layer located at opposite sides of the second insulating layer;
etching the fourth copper layer to form a second inner wiring layer, the second inner wiring layer defining a fifth opening aligned with the first opening;
laminating the second protective film on the second inner wiring layer, the second protective film defining the second opening aligned with the first opening, thereby obtaining a second printed circuit substrate.

18. The method of claim 10, wherein a shape of the third opening is same as that of the first opening, an area of the third opening being equal to or greater than that of the first opening.

19. A multilayer printed circuit board, comprising:
an adhesive sheet, the adhesive sheet defining a third opening;
a first protective film, the first protective film laminated on one side of the adhesive sheet, the first protective film defining a first opening, the first opening being aligned with and in communication with the third opening;
a second protective film, the second protective film laminated on an opposite side of the adhesive sheet to the first protective film, the second protective film defining a second opening, the second opening being aligned with and in communication with the first opening and the third opening;
a first inner wiring layer, the first inner wiring layer laminated on an opposite side of the first protective film to the adhesive sheet;
a second inner wiring layer, the second inner wiring layer laminated on an opposite side of the second protective film to the adhesive sheet;
a first insulating layer, the first insulating layer laminated on an opposite side of the first inner wiring layer to the first protective film;
a second insulating layer, the second insulating layer laminated on an opposite side of the second inner wiring layer to the second protective film;
a first outer wiring layer, the first outer wiring layer laminated on an opposite side of the first insulating layer to the first inner wiring layer;
a second outer wiring layer, the second outer wiring layer laminated on an opposite side of the second insulating layer to the second inner wiring layer;
there are two layers of the first outer wiring layer, the first inner wiring layer, the second inner wiring layer and the second outer wiring layer defining two fifth openings aligned with the third opening.

20. The multilayer printed circuit board of claim 19, wherein a shape of the second opening is same as that of the first opening, the second opening having an area equal to that of the first opening, a shape of the fifth opening being same as that of the first opening, the fifth opening having an area equal to that of the first opening.
